(19) United States
(12) Patent Application Publication
(10) Pub. No.: US 2012/0224342 A1
(43) Pub. Date: Sep. 6, 2012

(54) Flat Panel Display Apparatus, Mother Substrate for Flat Panel Display Apparatus, Method of Manufacturing the Flat Panel Display Apparatus, and Method of Manufacturing the Mother Substrate for the Flat Panel Display Apparatus

(75) Inventors: Jeong-Moon Kim, Yongin-City (KR); Dong-Seop Park, Yongin-City (KR); Oh-Seob Kwon, Yongin-City (KR); Jae-Sang Ro, Seoul (KR); Won-Eui Hong, Seoul (KR); Seog-Young Lee, Seoul (KR)

(73) Assignees: ENSIL TECH CO., LTD., Seoul (KR); SAMSUNG MOBILE DISPLAY CO., LTD., Yongin-City (KR)

(21) Appl. No.: 13/372,057

(22) Filed: Feb. 13, 2012

(30) Foreign Application Priority Data
Mar. 3, 2011 (KR) 10-2011-0019110

(51) Int. Cl. H05K 7/06; B32B 37/14; B32B 37/06

(52) U.S. Cl. 361/760; 156/275.7

(57) ABSTRACT

A flat panel display apparatus having improved encapsulating characteristics comprises: a substrate; a display unit on the substrate; a sealing substrate disposed facing the display unit; a sealing member between the substrate and the sealing substrate and surrounding the display unit; a wiring unit between the substrate and the sealing substrate and overlapping at least the sealing member, and including wiring members separated from each other; and an inlet unit electrically connected to a power source and the wiring unit for applying voltage to the wiring unit, and including an edge parallel with an outermost wiring member of the wiring unit. A mother substrate for the display apparatus comprises a substrate, a plurality of display units, a sealing substrate, a sealing member, wiring units, a connection unit, and an inlet unit. Methods of manufacturing the display apparatus and the mother substrate are also disclosed.

### CLAIM OF PRIORITY

This application makes reference to, incorporates the same herein, and claims all benefits accruing under 35 U.S.C. §119 from an application earlier filed in the Korean Intellectual Property Office on the 3^{rd} of March 2011 and there duly assigned Serial No. 10-2011-0019110.

### BACKGROUND OF THE INVENTION

1. Field of the Invention

The present invention relates to a flat panel display apparatus, a mother substrate for a flat panel display apparatus, a method of manufacturing the flat panel display apparatus, and a method of manufacturing the mother substrate for a flat panel display apparatus.

2. Description of the Related Art

Display apparatuses have recently been replaced with portable thin flat panel display apparatuses. In particular, flat panel display apparatuses, such as organic light-emitting display apparatuses and liquid crystal display apparatuses, have drawn attention for their good image quality.

In a flat panel display apparatus, a display unit is disposed on a substrate, and a sealing substrate is disposed on the display unit to protect the display unit. A sealing member is disposed between the substrate and the sealing substrate.

An encapsulating process is performed to protect the display unit from external moisture, any gaseous solutions, or other foreign substances. The performance of the flat panel display apparatus is determined greatly by encapsulating characteristics thereof.

The encapsulating characteristics of the flat panel display apparatus are determined by, for example, the performances of the sealing substrate and the sealing member, and particularly, by uniform characteristics of the sealing member.

However, it is not easy to manufacture such a sealing member, and thus, improving the encapsulating characteristics of the flat panel display apparatus is limited.

### SUMMARY OF THE INVENTION

The present invention provides a flat panel display apparatus, a mother substrate for a flat panel display apparatus, a method of manufacturing the flat panel display apparatus, and a method of manufacturing the mother substrate for a flat panel display apparatus.

According to an aspect of the present invention, a flat panel display apparatus comprises: a substrate; a display unit disposed on the substrate; a sealing substrate disposed facing the display unit; a sealing member disposed between the substrate and the sealing substrate so as to surround the display unit; a wiring unit disposed between the substrate and the sealing substrate so as to overlap at least the sealing member, the wiring unit including a plurality of wiring members disposed apart from each other; and an inlet unit electrically connected to an external power source and the wiring unit so as to apply voltage to the wiring unit, the inlet unit including edges located in parallel with an outermost wiring member from among the plurality of wiring members.

The inlet unit may include a body portion and a middle portion contacting the body portion. The middle portion may be connected to the wiring unit, and the width of the body portion is greater than the width of the wiring unit.

The inlet unit may include a body portion and a middle portion contacting the body portion. The middle portion maybe connected to the wiring unit, and the width of the middle portion may become reduced as the middle portion is more distant from the body portion.

The inlet unit may include a body portion and a middle portion contacting the body portion. The middle portion may be connected to the wiring unit and may overlap at least the sealing member.

A plurality of the inlet units may be formed at both sides of the display unit in such a manner that the inlet units are diagonally symmetric to each other with respect to a center of the display unit.

The inlet unit may be formed so as to correspond to at least one edge of the display unit.

The wiring members may have the same length.

The wiring members may become shorter as the wiring members are more distant from the display unit.

Edges of the plurality of wiring members may be rounded.

The plurality of wiring members may include a round wiring member disposed in a region corresponding to an edge of the wiring unit.

The plurality of wiring members may be disposed on the substrate, and the sealing member may be disposed between the plurality of wiring members and the sealing substrate and in spaces between adjacent wiring members from among the plurality of wiring members.

The sealing member may include frit.

The display unit may include an organic light-emitting diode or a liquid crystal display device.

According to another aspect of the present invention, a mother substrate for a flat panel display apparatus comprises: a substrate; a plurality of display units disposed apart form each other on the substrate so as to form a plurality of flat panel display apparatuses; a sealing substrate disposed facing the plurality of display units; a sealing member disposed between the substrate and the sealing substrate so as to respectively surround the plurality of display units; a plurality of wiring units disposed between the substrate and the sealing substrate so as to respectively correspond to the plurality of display units and so as to overlap at least the sealing member, each of the plurality of wiring units including a plurality of wiring members disposed apart from each other; a connection unit for connecting wiring units adjacent in one direction from among the plurality of wiring units, the connection unit including an edge connected in parallel with an outermost wiring member of the plurality of wiring units; and an inlet unit electrically connected to an external power source and the plurality of wiring units so as to apply voltage to the plurality of wiring units, each of the inlet units including an edge located in parallel with the outermost wiring member from among the plurality of wiring units.

The connection unit may include a body portion and end portions contacting the body portion. The end portions may be connected to the plurality of wiring units, and the width of each of the end portions becomes reduced as the end portions are more distant from the body portion.

The connection unit may include a body portion and end portions contacting the body portion. The end portions may be connected to the plurality of wiring units, and the width of the body portion may be greater than the width of each of the plurality of wiring units.

The connection unit may include a body portion and end portions contacting the body portion. The end portions may be located at both sides of the body portion and may be connected to wiring units corresponding to different display units from among the plurality of wiring units.

The connection unit may include a body portion and end portions contacting the body portion. The end portions may be connected to the plurality of wiring units and may overlap at least the sealing member.

At least three display units may be disposed, and the connection unit may be disposed at both sides of at least one display unit from among the at least three display units so as to be diagonally symmetric with respect to a center of the at least one display unit.

The connection unit may be formed so as to correspond to an edge of at least one display unit from among the plurality of display units.

According to another aspect of the present invention, a method of manufacturing a flat panel display apparatus comprises: preparing a substrate on which a display unit is disposed; disposing a sealing substrate facing the display unit; forming a sealing member between the substrate and the sealing substrate so as to surround the display unit; forming a wiring unit between the substrate and the sealing substrate so as to overlap at least the sealing member, the wiring unit including a plurality of wiring members disposed apart from each other; and forming an inlet unit electrically connected to an external power source and the wiring unit, the inlet unit including edges located in parallel with an outermost wiring member from among the plurality of wiring members. The forming of the sealing member includes preparing a material of the sealing member between the substrate and the sealing substrate, connecting the external power source to the inlet unit, and applying voltage to the wiring unit from the external power source and via the inlet unit so as to fuse and harden the material of the sealing member by using heat generated by the wiring unit.

The material of the sealing member may be obtained by preparing and baking a frit paste.

According to another aspect of the present invention, a method of manufacturing a mother substrate for a flat panel display apparatus comprises: preparing a substrate on which a plurality of display units are disposed so as to form a plurality of flat panel display apparatus; disposing a sealing substrate facing the plurality of display units; disposing a sealing member between the substrate and the sealing substrate so as to respectively surround the plurality of display units; forming a plurality of wiring units between the substrate and the sealing substrate so as to respectively correspond to the plurality of display units and so as to overlap at least the sealing member, each of the plurality of wiring units including a plurality of wiring members disposed apart from each other; forming a connection unit for connecting wiring units adjacent in one direction from among the plurality of wiring units, the connection unit including an edge connected in parallel to an outermost wiring member of the plurality of wiring units; and forming an inlet unit electrically connected to an external power source and the plurality of wiring units, the inlet unit including an edge located in parallel with the outermost wiring member from among the plurality of wiring members. The forming of the sealing member includes preparing a material of the sealing member between the substrate and the sealing substrate, connecting the external power source to the plurality of inlet units, and applying voltage to the plurality of wiring units from the external power source and via the inlet unit so as to fuse and harden the material of the sealing member by using heat generated by the wiring unit.

The material of the sealing member may be obtained by preparing and baking a frit paste.

### BRIEF DESCRIPTION OF THE DRAWINGS

A more complete appreciation of the invention, and many of the attendant advantages thereof, will be readily apparent as the same becomes better understood by reference to the following detailed description when considered in conjunction with the accompanying drawings, in which like reference symbols indicate the same or similar components, wherein:

FIG. 1 is a schematic plan view of a flat panel display apparatus according to an embodiment of the present invention;

FIG. 2 is a cross-sectional taken along the line II-II of FIG. 1.

FIG. 3 is an enlarged view of a region A illustrated in FIG. 2.

FIG. 4 is a schematic plan view illustrating an operation of manufacturing a sealing member during the manufacture of the flat panel display apparatus of FIG. 1 according to an embodiment of the present invention;

FIG. 5 is a schematic plan view of a mother substrate for a flat panel display apparatus according to an embodiment of the present invention; and

FIG. 6 is a schematic plan view illustrating an operation of manufacturing a sealing member during the manufacture of the mother substrate for the flat panel display apparatus of FIG. 5 according to another embodiment of the present invention.

### DETAILED DESCRIPTION OF THE INVENTION

Hereinafter, exemplary embodiments of the present invention will be described in detail with reference to the accompanying drawings.

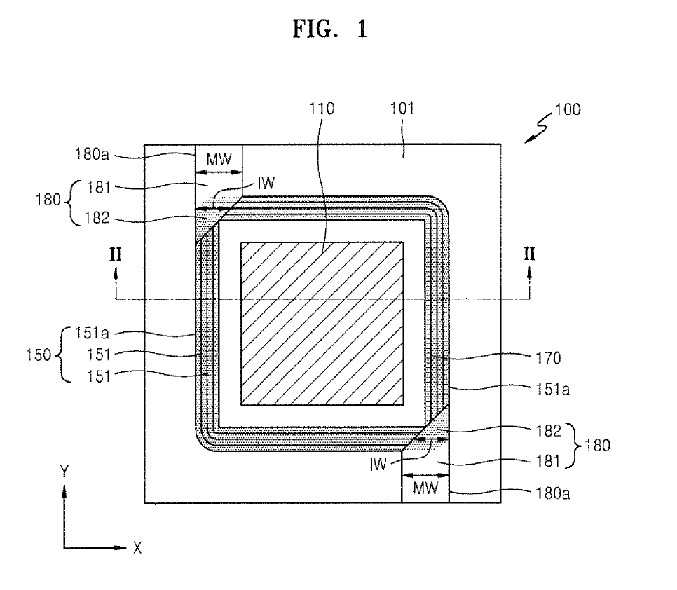

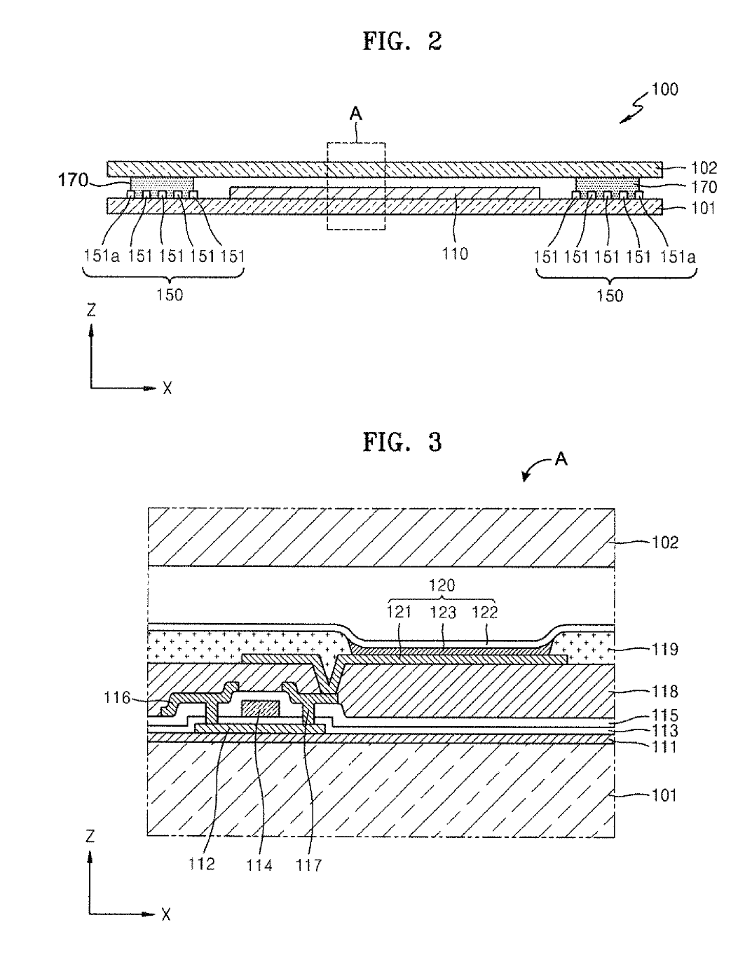

FIG. 1 is a schematic plan view of a flat panel display apparatus 100 according to an embodiment of the present invention; FIG. 2 is a cross-sectional taken along the line II-II of FIG. 1; and FIG. 3 is an enlarged view of a region A illustrated in FIG. 2.

In FIG. 1, the sealing substrate 102 of FIG. 2 is not illustrated but a sealing member 170 is illustrated as a dotted region for convenience of explanation.

Referring to FIGS. 1 thrus 3, the flat panel display apparatus 100 includes a substrate 101, a display unit 110, the sealing substrate 102, a wiring unit 150, the sealing member 170, and inlet units 180. The wiring unit 150 includes a plurality of wiring members 151.

The elements of the flat panel display apparatus 100 will now be described in detail with reference to FIGS. 1 thru 3. The substrate 101 may be formed of a SiO₂-based transparent glass material, but is not limited thereto and may be formed of a transparent plastic material. In this case, the transparent plastic material may be an organic material selected from an insulating organic material group consisting of polyethersulphone (PES), polyacrylate (PAR), polyetherimide (PEI), polyethyelenen napthalate (PEN), polyethyeleneterepthalate (PET), polyphenylene sulfide (PPS), polyallylate, polyimide, polycarbonate (PC), cellulose triacetate (TAC), and cellulose acetate propionate (CAP).

A plurality of display units 110 are disposed on the substrate 101. The shape of the display unit 110 is not limited. In the current embodiment, the display unit 110 includes an organic light-emitting device (OLED) 120 but is not limited thereto, and may include a liquid crystal display device.

The sealing substrate 102 is disposed facing the display unit 110. The sealing member 170 is disposed between the substrate 101 and the sealing substrate 102. The sealing member 170 is formed so as to surround the display unit 110. The sealing member 170 facilitates combining the substrate 101 with the sealing substrate 102. The sealing member 170 may contain frit.

The wiring unit 150 is formed so as to overlap the sealing member 170. That is, the wiring unit 150 is formed so as to surround the display unit 110. The wiring unit 150 is disposed on the substrate 101, the sealing member 170 is disposed on the wiring unit 150, and the sealing substrate 102 is disposed on the sealing member 170.

The wiring unit 150 includes a plurality of wiring members 151. The plurality of wiring members 151 include an outermost wiring member 151a which forms an outermost surface of the wiring unit 150. The wiring members 151 are disposed apart from each other. The wiring members 151 may be formed of various conductive materials.

The plurality of wiring members 151 are disposed on the substrate 101, the sealing member 170 is disposed on the plurality of wiring members 151, and the sealing substrate 102 is disposed on the sealing member 170. Also, the sealing member 170 is disposed in spaces between the wiring members 151 and contacts the substrate 101.

Since the sealing member 170 contacts the substrate 101 via the spaces between the wiring members 151, the sealing member 170 may be stably combined with the substrate 101, thereby improving coupling between the substrate 101 and the sealing substrate 102.

The plurality of wiring members 151 of the wiring unit 150 will now be described in detail. The sealing member 170 may be manufactured by disposing a material of the sealing member 170 between the substrate 101 and the sealing substrate 102 and applying voltage to the wiring unit 150 from an external power source so as to generate joule heat in the wiring unit 150, causing the material of the sealing member 170 to be fused and hardened by the joule heat.

In general, if the wiring unit 150 is a single wire having a width corresponding to the width of the sealing member 170, a center portion and edge portions of the wiring unit 150 are heated to different temperatures when voltage is applied to the wiring unit 150. Thus, the center portion and edge portions of the sealing member 170 may have different temperatures according to the width of the sealing member 170. If the center portion and edge portions of the sealing member 170 have different temperatures according to the width of the sealing member 170, the material of the sealing member 170 may be unevenly fused and hardened, thereby lowering the durability of the sealing member 170.

However, the wiring unit 150 according to the current embodiment of the invention includes the plurality of wiring members 151 disposed apart from each other in a region where the wiring unit 150 overlaps the sealing member 170. Since voltage is applied to the plurality of wiring members 151 and the plurality of wiring member 151 generate heat, it is possible to prevent the center portion and edge portions of the wiring unit 150 from having different temperatures according to the width of the sealing member 170.

Referring to FIG. 1, the wiring unit 150 is illustrated similar to a tetragonal type so as to correspond to a tetragonal shape of the display unit 110. The wiring unit 150 has two edges, i.e., an upper right side edge and a lower right side edge. If the wiring unit 150 is a single wire having a width corresponding to that of the sealing member 170, then current unevenly flows through inside portions and edge portions of edge regions of the wire, that is, portions of the wire adjacent to the display unit 110 and the other portions of the wire distant from the display unit 110. Thus, since the inside portions of the edge regions of the wire have a shorter current path than the edge portions of the edge regions of the wire, a large amount of current flows through the inside portions. Thus, when voltage is applied to the single wire, an amount of heat generated in the inside portions of the edge regions thereof, which are adjacent to the display unit 110, abnormally increases, thereby causing the material of the sealing member 170 to be unevenly fused and hardened.

However, the wiring unit 150 of the present invention includes a plurality of wiring members 151 as described above. That is, in the edge regions of the wiring unit 150, the plurality of wiring members 151 act as individual current paths. Thus, it is possible to prevent current from unevenly flowing through the inside portions and edge portions of the edge regions of the wiring unit 150. In detail, it is possible to prevent a large amount of current from flowing through the inside portions of the edge regions of the wiring unit 150 adjacent to the display unit 110, thereby allowing current to evenly flow through the whole edge regions of the wiring unit 150. Accordingly, the sealing member 170 may be evenly heated.

In particular, the wiring unit 150 may include the plurality of wiring members 151, the edges of which are not squared but are rounded. Thus, it is possible to more effectively prevent voltage from being abnormally applied to the edge portions of the wiring unit 150. Referring to FIG. 1, the edges of an innermost wiring member 151 from among the plurality of wiring members 151 are squared but are not limited thereto, and they may be rounded so that current may more evenly flow through the edge regions of the wiring unit 150.

The width of the wiring unit 150 may correspond to that of the sealing member 170 or may be slightly less than or greater than that of the sealing member 170 according to process conditions.

The inlet units 180 are formed so as to be respectively connected to the corresponding wiring units 150. The inlet units 180 include an edge 180a which is connected in parallel with the outermost wiring member 151a of the wiring unit 150. On the whole, the inlet units 180 are formed in parallel with the outermost wiring member 151a. Another edge of the inlet units 180 facing the edge 180a may be parallel with the edge 180a.

Also, the inlet units 180 are formed so as to correspond to edges of the display units 110.

The inlet units 180 are respectively formed on a first end of the substrate 101 and a second end of the substrate facing the first end so that the inlet units 180 may be easily connected to an external power source (not shown).

If the inlet units 180 are formed so as to correspond to the edges of the display unit 110, a space on the substrate (i.e., a region on the substrate 101 around the wiring unit 150) may be effectively used. In particular, since the edge 180a of the inlet units 180 is located in parallel with the outermost wiring member 151 a, use of a space on the substrate 101 may be optimized and manufacturing efficiency of the flat panel display apparatus 100 may be improved. On the other hand, the edge regions of the wiring unit 150 may be abnormally heated as described above. To solve this problem, the inlet units 180 may be formed so as to correspond to the edges of the display unit 110 so that the total number of edges of the wiring unit 150 may be reduced from four to two. In this way, it is possible to basically prevent the edge regions of the wiring unit 150 from being abnormally heated.

Each of the inlet units 180 includes a body portion 181 and a middle portion 182. The middle portions 182 are connected to the plurality of wiring members 151. The body portions 181 are disposed adjacent to an end of the substrate 101 so that the inlet units 180 may be easily connected to an external power source (not shown).

The body portions 181 have a width MW which is wider than the width of the wiring unit 150. The width MW of the body portions 181 may be greater than the sum of widths of the plurality of wiring members 151. As described above, voltage is applied to the wiring unit 150 so as to heat the material of the sealing member 170 during the manufacture of the sealing member 170. In detail, the voltage is applied to the wiring unit 150 from the external power source via the body portions 181 of the inlet units 180. Then, current flows through the wiring unit 150. Specifically, referring to FIG. 1, both current flowing through a region of the wiring unit 150 corresponding to a left side of the display unit 110 and current flowing through a region of the wiring unit 150 corresponding to a right side of the display unit 110 flow together through the body portions 181.

That is, the voltage is applied to the wiring unit 150 so as to generate heat for fusing the material of the sealing member 170 during the manufacture of the sealing member 170. In this case, both currents respectively flowing through the regions of the wiring unit 150 corresponding to the left and right sides of the display unit 110 simultaneously flow through the body portions 181. Thus, a higher load is applied to the body portions 191 than to the wiring unit 150. In the current embodiment, the body portions 181 are formed so as to be wider than the wiring unit 150, thereby preventing the body portions 181 from being abnormally heated. In particular, if the width MW of each of the body portions 181 is two times or more than the sum of the widths of the plurality of wiring members 151 (that is, if the width MW of the each of body portions 181 is greater than the sum of the widths of the plurality of wiring members 151 corresponding to the left side of the display unit 110 and the widths of the plurality of wiring members 151 corresponding to the right side of the display unit 110), then the amount of heat generated by the body portions 181 may be controlled so as to be similar to the amount of heat generated by the wiring unit 150.

The middle portions 182 are connected to the plurality of wiring members 151. The middle portions 182 have an irregular width IW. The greater the difference between the middle portions 182 and the body portions 181, the less the width IW.

The lengths of the wiring members 151 may vary according to the shape of the middle portions 182. That is, the wiring members 151 may be controlled so as to be the same. If the lengths of the wiring members 151 are the same, current may evenly flow through the wiring members 151 so that the amounts of heat generated by the wiring members 151 may be the same when voltage is applied to the wiring units 550 during the manufacture of the sealing members 170, thereby obtaining uniform characteristics of the sealing members 170.

However, the present invention is not limited to the above description, and the lengths of the wiring members 151 may be determined in such a manner that the greater the distance between a wiring member 151 and the display unit 110, the shorter the wiring member 151. In the edge regions of the wiring unit 150, the inside portions have a current path which is more bent than the current path of the edge portions. Thus, even if the inside portions and edge portions of the wiring unit 150 have the same current path, the inside portions may be abnormally heated. In this case, outer wiring members 151 from among the plurality of wiring members 151 may be controlled so as to be shorter than the other wiring members 151, thereby preventing the inside portions of the edge regions of the wiring unit 150 from being abnormally heated.

As illustrated in FIG. 1, the middle portions 182 at least overlap the sealing member 170.

Since each of the inlet units 180 includes the body portion 181 and the middle portion 182 in a single body, current may be stably supplied to the whole wiring unit 150 when voltage is applied to the wiring unit 150 from an external power source (not shown), thereby obtaining uniform characteristics of the sealing member 170.

The inlet units 180 may be formed of the same material used to form the wiring unit 150. The inlet units 180 are respectively disposed at both sides of the display unit 110 so as to be connected to an external power source (not shown), and particularly, maybe diagonally symmetric to each other with respect to a center of the display unit 110.

According to the present invention, the shape of the display unit 110 is not limited and the display unit 110 according to the current embodiment employs an organic light-emitting diode (OLED). The display unit 110 will now be described in detail with reference to FIG. 3.

A buffer layer 111 is formed on the substrate 101. The buffer layer 111 may provide a flat surface on the substrate 101 and protects the substrate 101 from external moisture or substances.

An active layer 112 having a predetermined pattern is formed on the buffer layer 111. The active layer 112 may be formed of an inorganic semiconductor material, such as amorphous silicon or polysilicon, or an organic semiconductor material. The active layer 112 includes a source region, a drain region, and a channel region.

The source and drain regions of the active layer 112 may be formed by doping impurities into the amorphous silicon or the polysilicon. A gate insulating layer 113 is formed on the active layer 112, and a gate electrode 114 is formed in a predetermined region of the gate insulating layer 113. The gate insulating layer 113 insulates the active layer 112 and the gate electrode 114 from each other, and may be formed of an organic material or an inorganic material, such as SiNₓ or SiO₂.

The gate electrode 114 may be formed of a material selected from the group consisting of gold (Au), silver (Ag), copper (Cu), nickel (Ni), platinum (Pt), palladium (Pd), aluminum (Al), molybdenum (Mo), an Al:Nd alloy, and an Mo:W alloy, but is not limited thereto, and may be formed of various materials in consideration of adhesion property, planarizability, electric resistance, processing suitability, etc. The gate electrode 114 is connected to a gate line (not shown) which supplies an electrical signal.

An interlayer insulating layer 115 is formed on the gate electrode 114. The interlayer insulating layer 115 and the gate insulating layer 113 are formed so as to expose the source and drain regions of the active layer 112. A source electrode 116 and a drain electrode 117 are formed in contact with the exposed source and drain regions, respectively, of the active layer 112.

The source electrode 116 and the drain electrode 117 may be formed of, but is not limited to, metal or a metal alloy selected from the group consisting of Au, Pd, Pt, Ni, Rh, Ru, Ir, Os, an Al, Mo, an Al:Nd alloy, and a MoW alloy.

A passivation layer 118 is formed so as to cover the source electrode 116 and the drain electrode 118. The passivation layer 118 may include an inorganic insulating layer and/or an organic insulating layer. Examples of the inorganic insulating layer include SiO₂, SiNₓ, SiON, Al₂O₃, TiO₂, Ta₂O₅, HfO₂, ZrO₂, BST, and PZT. Examples of the organic insulating layer include a general commercial polymer, e.g., polymethyl-methacrylate (PMMA) or poly styrene (PS), phenol group-based polymer derivative, acryl-based polymer, imide-based polymer, aryl ether-based polymer, amide-based polymer, fluorinated polymer, p-xylene-based polymer, vinyl alcohol-based polymer, and a composition thereof. The passivation layer 118 may be a stacked structure of an inorganic insulating layer and an organic insulating layer.

The passivation layer 118 is formed so as to expose the drain electrode 117, and an organic light-emitting device (OLED) 120 is formed so as to be connected to the exposed drain electrode 117. The OLED includes a first electrode 121, a second electrode 122, and an intermediate layer 123. Specifically, the first electrode 121 and the drain electrode 117 contact each other.

The intermediate layer 123 includes an organic emission layer. When voltage is applied to the intermediate layer 123 via the first and second electrodes 121 and 122, respectively, the organic emission layer emits visible light.

A pixel defining layer 119 is formed on the first electrode 121 by using an insulating material. A predetermined aperture is formed in the pixel defining layer 119 so as to expose the first electrode 121. The intermediate layer 123 is formed on the exposed first electrode 121. The second electrode 122 is formed so as to be connected to the intermediate layer 123.

The first electrode 121 may function as an anode electrode and the second electrode 122 may function as a cathode electrode, or vice versa.

The sealing substrate 102 is disposed on the second electrode 122.

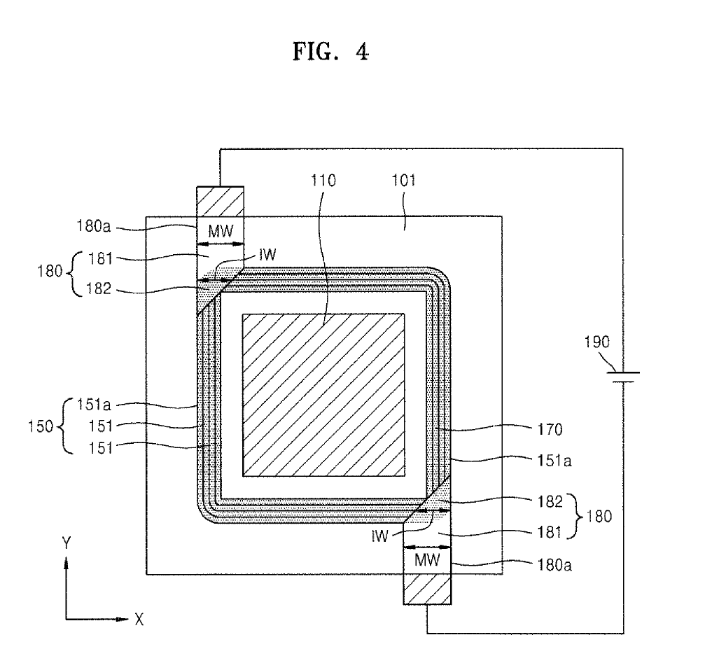

FIG. 4 is a schematic plan view illustrating an operation of manufacturing the sealing member 170 during the manufacture of the flat panel display apparatus 100 of FIG. 1 according to an embodiment of the present invention. In detail, FIG. 4 illustrates a process of applying voltage to the wiring unit 150 via an external power source 190 so as to form the sealing member 170.

A process of manufacturing the flat panel display apparatus 100 of FIG. 1 includes various operations, one of which is an operation of manufacturing the sealing member 170. The operation of manufacturing the sealing member 170 includes preparing, fusing, and hardening a material of the sealing member 170. For example, the sealing member 170 may contain frit, and the operation of manufacturing the sealing member 170 may include forming, baking, fusing and hardening a frit paste.

During the fusing of the frit paste, each terminal of the external power source 190 is connected to a respective one of the inlet units 180. Then, voltage generated by the external power source 190 is applied to the wiring units 150 via the inlet units 180 so as to generate joule heat in the wiring units 150. When the wiring units 150 generate the joule heat, portions of the materials of the sealing members 170, which overlap the wiring units 150, are fused and hardened. Also, the remaining materials of the sealing members 170 which overlap the inlet units 180 are fused and hardened, thereby obtaining the sealing members 170. The sealing member 170 facilitates combining the substrate 101 with the sealing substrate 102.

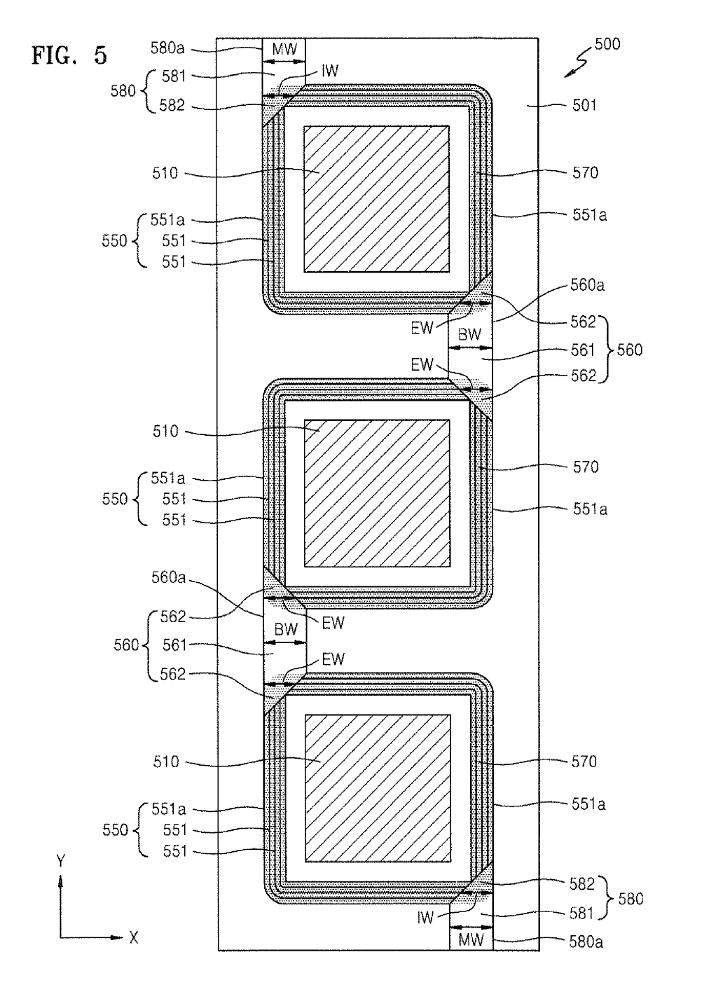

FIG. 5 is a schematic plan view of a mother substrate for a flat panel display apparatus according to an embodiment of the present invention. In FIG. 5, a sealing substrate is not illustrated but sealing members 570 are illustrated as dotted regions for convenience of explanation.

Referring to FIG. 5, the mother substrate 500 includes a substrate 501, a plurality of display units 510, a sealing substrate (not shown), a plurality of wiring units 550, a plurality of connection units 560, the plurality of sealing members 570, and a plurality of inlet units 580. Each of the wiring units 550 includes a plurality of wiring members 551.

The plurality of display units 510 are disposed on the substrate 501. Each of the display units 510 forms a flat panel display apparatus. FIG. 5 illustrates a total of three display units 510. Thus, three flat panel display apparatuses may be manufactured using the mother substrate 500 for a flat panel display apparatus according to the current embodiment. However, the present invention is not limited thereto, and the total number of display units 510 which may be included in the mother substrate 500 for a flat panel display apparatus is not limited.

The sealing substrate is disposed facing the plurality of display units 510. The plurality of sealing members 570 are disposed between the substrates 501 and the sealing substrate. The sealing members 570 are respectively formed so as to surround the display units 510.

The wiring units 550 are formed so as to overlap the sealing member 570. The wiring units 550 are respectively formed so as to surround the display units 510. In the current embodiment, three wiring units 550 are formed in correspondence with the display units 510. Each of the wiring units 550 includes a plurality of wiring members 551.

Although not shown, the wiring units 550 are disposed on the substrate 501, the sealing members 570 are respectively disposed on the wiring units 550, and the sealing substrate is disposed on the sealing members 570. Also, the sealing members 570 are disposed in spaces between the plurality of wiring members 551 and contact the substrate 501. Since the sealing members 570 contact the substrate 501 via the spaces between the plurality of wiring members 551, the sealing members 570 may be stably combined with the substrate 501, thereby improving coupling between the substrate 501 and the sealing substrate.

Each of the wiring units 550 includes a plurality of wiring members 551. The wiring members 551 include an outermost wiring member 551a which forms an outermost surface of the wiring unit 150. The wiring members 551 are disposed apart from each other.

The structure of each wiring unit 550 is similar to that of the wiring unit 150 in the previous embodiment, and will not be described here in detail.

Referring to FIG. 5, the three wiring units 550 of FIG. 5 are arranged in one direction, e.g., a Y-axis direction. The connection units 560 are respectively disposed between wiring units 550 disposed adjacent in one direction, i.e., the Y-axis direction. The connection units 560 connect the adjacent wiring units 550 to one another. The connection units 560 contain a conductive material and may be formed of the same material used to form the wiring units 550.

The connection units 560 include edges 560a which are respectively in parallel with the outermost wiring members 551a of the wiring units 550. On the whole, the connection units 560 are formed so as to be respectively in parallel with the outermost wiring members 551a. The other edges of the connection units 560 facing the edges 560a may be in parallel with the edges 560a.

Also, each of the connection units 560 corresponds to an edge of one of the display units 510.

If the connection units 560 are formed so as to correspond to edges of the display units 510, a space on the substrate 501 may be efficiently used. In particular, since the edges 560a of the connection units 560 are disposed so as to be respectively in parallel with the outermost wiring members 551a, use of a space on the substrate 501 may be optimized and manufacturing efficiency of the mother substrate 500 may be improved. On the other hand, the edge regions of the wiring units 550 may be abnormally heated. To solve this problem, the connection units 560 may be formed so as to correspond to the edges of the display units 510 so that the total number of edges of the wiring unit 550 may be reduced from four to two. In this way, it is possible to basically prevent the edge regions of the wiring unit 550 from being abnormally heated.

Each of the connection units 560 includes a body portion 561 and end portions 562. The end portions 562 are connected to the plurality of wiring members 551. Specifically, the end portions 562 are located at both ends of the body portion 561, and are respectively connected to the wiring members 551 corresponding to different display units 510.

The body portion 561 of each of the body portions 560 has a width BW which is wider than a width of each of the wiring units 550. The width BW of the body portion 561 may be greater than the sum of widths of the plurality of wiring members 551. Voltage is applied to the wiring units 550 to heat materials of the sealing members 570 during the manufacture of the sealing members 170. Then, current flows through the wiring units 550. Specifically, referring to FIG. 5, both current flowing through a region of each of the wiring units 550 which corresponds to a rectangular type left side of one of the display units 510 and current flowing through a region of each of the wiring units 550 which corresponds to a right side of the display unit 510 flow together through the body portions 561.

That is, the voltage is applied to the wiring units 550 to generate heat for fusing the materials of the sealing members 570 during the manufacture of the sealing members 570. In this case, both currents respectively flowing through the regions of each of the wiring units 550 corresponding to the left and right sides of the corresponding display unit 510 simultaneously flow through the body portions 561. Thus, a higher load is applied to the body portions 561 than to the wiring units 550. In the current embodiment, the body portions 561 of the connection units 560 are formed so as to be wider than the wiring unit 561, thereby preventing the body portions 561 from being abnormally heated. In particular, if the width BW of each of the body portions 561 is two times or more than the width of the plurality of corresponding wiring members 551, the amount of heat generated by the body portion 561 may be controlled so as to be similar to the amount of heat generated by the wiring unit 550.

The end portions 562 are connected to the plurality of wiring members 551. Each of the end portions 562 has an irregular width EW. The greater the difference between each of the end portions 562 and the body portion 561, the less the width BW. The lengths of the plurality of wiring members 551 may vary according to the shapes of the end portions 562. That is, the plurality of wiring members 551 may be controlled to be the same. If the lengths of the plurality of wiring members 551 are the same, current may be evenly supplied to the plurality of wiring members 551 so that the amounts of heat generated by the plurality of wiring members 551 may be the same when voltage is applied to the wiring units 550 during the manufacture of the sealing members 570, thereby obtaining uniform characteristics of the sealing members 570.

However, the present invention is not limited to the above description, and the lengths of the plurality of wiring members 551 may be determined in such a manner that the greater the distance between a wiring member 551 and the display unit 510, the shorter the wiring member 551. In this case, outer wiring members 551 from among the plurality of wiring members 551 may be controlled so as to be shorter than the other wiring members 551, thereby preventing inside portions of edge regions of the wiring units 550 from being abnormally heated.

The end portions 562 at least overlap the corresponding sealing members 570, respectively.

Since each of the connection units 560 includes the body portion 561 and the end portions 562 in a single body, current may be stably supplied to the entirety of the wiring units 550 when voltage is applied to the wiring units 550 from an external power source (not shown), thereby obtaining uniform characteristics of the sealing members 570.

The connection units 560 may be formed of the same material used to form the wiring units 550. When three or more display units 510 are disposed on the substrate 501, two or more connection units 560 are formed so as to be diagonally symmetric to each other with respect to a center of the middle display unit 510 from among the three or more display units 510.

The inlet units 580 are formed so as to be respectively connected to the wiring units 550. Specifically, the inlet units 580 are formed so as to be respectively connected to the pluralities of wiring units 550 corresponding to two display units 510 disposed at both ends of the substrate 501.

The inlet units 580 include edges 580a which are located in parallel with the outermost wiring members 551a of the wiring units 550. On the whole, the inlet units 580 are formed in parallel with the outermost wiring member 551a. Also, the inlet units 580 are formed so as to correspond to edges of the display units 510.

The inlet units 580 are respectively formed on a first end of the substrate 501 and a second end of the substrate facing the first end so that the inlet units 580 may be easily connected to an external power source (not shown).

If the connection units 580 are formed so as to correspond to the edges of the display units 510, a space on the substrate 501 may be efficiently used and manufacturing efficiency of the mother substrate 500 may be improved. If the inlet units 580 are formed so as to correspond to the edges of the display units 510, the total number of edges of each of the wiring units 550 may be reduced from four to two, thereby minimizing abnormal heating of the wiring units 550.

Each of the connection units 580 includes a body portion 581 and a middle portion 582. The middle portion 582 is connected to the plurality of wiring members 551. The body portion 581 is disposed adjacent to an end of the substrate 501 so that the inlet unit 580 may be easily connected to an external power source (not shown).

The body portion 581 has a width MW which is wider than the width of the wiring unit 550. The width MW of the body portion 581 may be greater than the sum of the widths of the wiring members 551. In particular, if the width MW of the body portion 581 is two times or more than the widths of the wiring members 551, the amount of heat generated by the body portion 581 may be controlled so as to be similar to the amount of heat generated by the wiring unit 550.

The middle portion 582 is connected to the plurality of wiring members 551. The middle portion 582 has an irregular width IW. The greater the differences between the middle portion 582 and the body portion 581, the less the width IW.

The lengths of the wiring members 551 may vary according to the shape of the middle portion 582. That is, the wiring members 551 may be controlled to be the same. However, the present invention is not limited to the above description, and the wiring members 551 may become shorter as they are more distant from the display unit 510 (i.e., the outermost wiring member 551a may be the shortest).

The middle portion 582 at least overlaps the corresponding sealing member 570. Since each of the inlet units 580 includes the body portion 581 and the middle portion 582 in a single body, current may be stably supplied to the entire wiring unit 550 when voltage is applied to the wiring unit 550 from an external power source (not shown), thereby obtaining uniform characteristics of the sealing member 570.

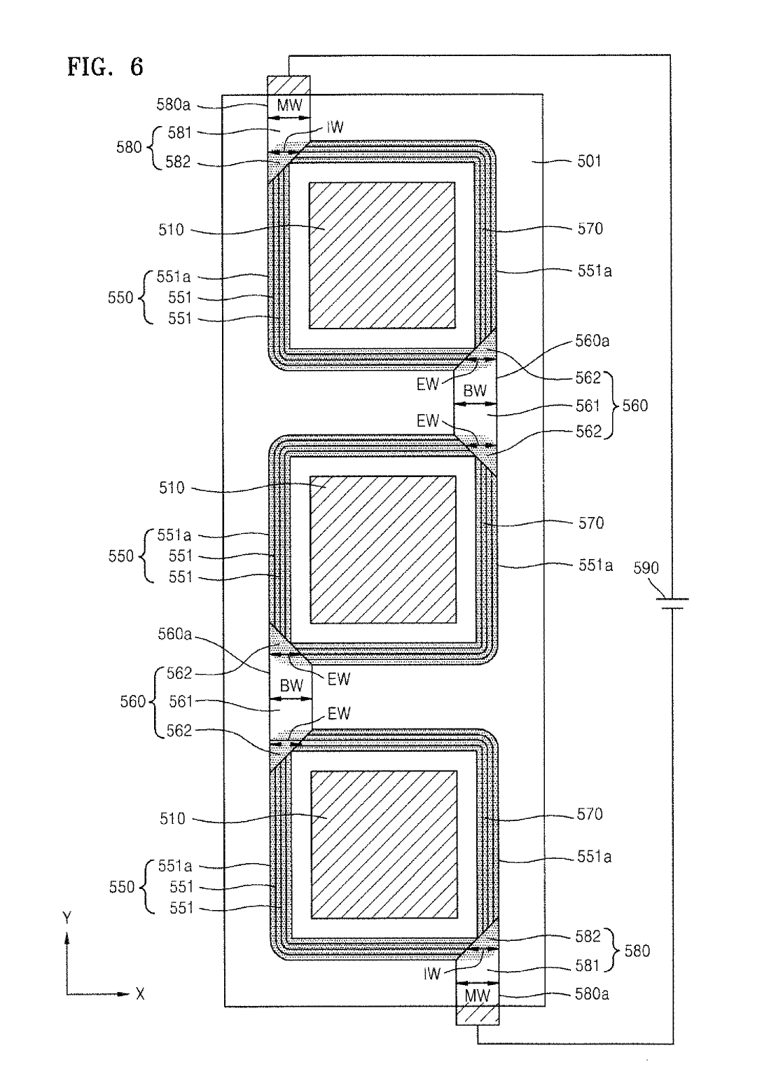

FIG. 6 is a schematic plan view illustrating an operation of manufacturing a sealing member during the manufacture of the mother substrate for the flat panel display apparatus of FIG. 5 according to another embodiment of the present invention. In detail, FIG. 6 illustrates a process of applying voltage to the wiring units 550 via an external power source 590 so as to form the sealing members 570.

The process of manufacturing the mother substrate 500 for a flat panel display apparatus of FIG. 5 includes various operations, one of which is an operation of manufacturing the sealing members 570. The operation of manufacturing the sealing members 570 includes preparing, fusing, and hardening a material of the sealing member 570. For example, the sealing members 570 may contain frit, and the operation of manufacturing the sealing members 570 may include forming, baking, fusing and hardening a frit paste.

During the fusing of the frit paste, each terminal of the external power source 590 is connected to a respective one of the inlet units 580. Then, voltage generated by the external power source 590 is applied to the wiring units 550 via the inlet units 580 so as to generate joule heat in the wiring units 550. In detail, voltage is applied to the wiring units 550 corresponding to the display units 510 disposed on upper and lower portions of the substrate 501 via the inlet units 580, and is then applied to the wiring unit 550 corresponding to the middle display unit 510 via the connection units 560.

When the wiring units 550 generate the joule heat, portion of the materials of the sealing members 570, which overlap the wiring units 550, are fused and hardened. Also, the remaining materials of the sealing members 570 which overlap the inlet units 580 are fused and hardened, thereby obtaining the sealing members 570. The sealing members 570 facilitate combining the substrate 501 with the sealing substrate.

Although not shown, during a subsequent operation, the resultant structure is divided into regions including one of the display units 510 and one of the sealing members 570 surrounding the display units 510, thereby obtaining a plurality of flat panel display apparatuses.

The above embodiments provide a flat panel display apparatus, the encapsulating characteristics of which are improved, a mother substrate for such a flat panel display apparatus, a method of manufacturing the flat panel display apparatus, and a method of manufacturing the mother substrate for such a flat panel display apparatus.

While the present invention has been particularly shown and described with reference to exemplary embodiments thereof, it will be understood by those of ordinary skill in the art that various changes in form and detail maybe made therein without departing from the spirit and scope of the present invention as defined by the following claims.

What is claimed is:

1. A flat panel display apparatus, comprising:
a substrate;
a display unit disposed on the substrate;
a sealing substrate disposed facing the display unit;
a sealing member disposed between the substrate and the sealing substrate and surrounding the display unit;
a wiring unit disposed between the substrate and the sealing substrate so as to overlap at least the sealing member, the wiring unit including a plurality of wiring members disposed apart from each other; and
an inlet unit electrically connected to an external power source and the wiring unit for applying voltage to the wiring unit, the inlet unit including edges located in parallel with an outermost wiring member from among the plurality of wiring members.

2. The flat panel display apparatus of claim 1, wherein the inlet unit comprises a body portion and a middle portion contacting the body portion; and
wherein the middle portion is connected to the wiring unit, and a width of the body portion is greater than a width of the wiring unit.

3. The flat panel display apparatus of claim 1, wherein the inlet unit comprises a body portion and a middle portion contacting the body portion; and
wherein the middle portion is connected to the wiring unit, and a width of the middle portion becomes reduced as the middle portion is more distant from the body portion.

4. The flat panel display apparatus of claim 1, wherein the inlet unit comprises a body portion and a middle portion contacting the body portion; and
wherein the middle portion is connected to the wiring unit and overlaps at least the sealing member.

5. The flat panel display apparatus of claim 1, wherein a plurality of the inlet units are formed at both sides of the display unit in such a manner that the plurality of the inlet units are diagonally symmetric relative to each other with respect to a center of the display unit.

6. The flat panel display apparatus of claim 1, wherein the inlet unit is formed so as to correspond to at least one edge of the display unit.

7. The flat panel display apparatus of claim 1, wherein the plurality of wiring members have a same length.

8. The flat panel display apparatus of claim 1, wherein the plurality of wiring members become shorter as the plurality of wiring members are more distant from the display unit.

9. The flat panel display apparatus of claim 1, wherein edges of the plurality of wiring members are rounded.

10. The flat panel display apparatus of claim 1, wherein each of the wiring members comprises a round wiring member disposed in a region corresponding to an edge of the wiring unit.

11. The flat panel display apparatus of claim 1, wherein the plurality of wiring members are disposed on the substrate, and the sealing member is disposed between the plurality of wiring members and the sealing substrate and in spaces between adjacent wiring members from among the plurality of wiring members.

12. The flat panel display apparatus of claim 1, wherein the sealing member comprises frit.

13. The flat panel display apparatus of claim 1, wherein the display unit comprises one of an organic light-emitting diode and a liquid crystal display device.

14. A mother substrate for a flat panel display apparatus, the mother substrate comprising:
a substrate;
a plurality of display units disposed apart from each other on the substrate so as to form a plurality of flat panel display apparatuses;
a sealing substrate disposed facing the plurality of display units;
a sealing member disposed between the substrate and the sealing substrate and respectively surrounding the plurality of display units;
a plurality of wiring units disposed between the substrate and the sealing substrate so as to respectively correspond to the plurality of display units and overlapping at least the sealing member, each of the plurality of wiring units including a plurality of wiring members disposed apart from each other;
a connection unit for connecting wiring units adjacent in one direction from among the plurality of wiring units, the connection unit including an edge connected in parallel with an outermost wiring member of the plurality of wiring units; and
an inlet unit electrically connected to an external power source and the plurality of wiring units for applying voltage to the plurality of wiring units, each of the plurality of inlet units including an edge located in parallel with the outermost wiring member of the plurality of wiring units.

15. The mother substrate of claim 14, wherein the connection unit comprises a body portion and end portions contacting the body portion; and
wherein the end portions are connected to the plurality of wiring units, and a width of each of the end portions becomes reduced as the end portions are more distant from the body portion.

16. The mother substrate of claim 14, wherein the connection unit comprises a body portion and end portions contacting the body portion; and
wherein the end portions are connected to the plurality of wiring units, and a width of the body portion is greater than a width of each of the plurality of wiring units.

17. The mother substrate of claim 14, wherein the connection unit comprises a body portion and end portions contacting the body portion; and
wherein the end portions are located at both sides of the body portion and are connected to wiring units corresponding to different display units from among the plurality of wiring units.

18. The mother substrate of claim 14, wherein the connection unit comprises a body portion and end portions contacting the body portion; and
wherein the end portions are connected to the plurality of wiring units and overlap at least the sealing member.

19. The mother substrate of claim 14, wherein at least three display units are disposed; and
wherein the connection unit is disposed at both sides of at least one display unit from among said at least three display units so as to be diagonally symmetric with respect to a center of said at least one display unit.

20. The flat panel display apparatus of claim 14, wherein the connection unit is formed so as to correspond to an edge of at least one display unit from among the plurality of display units.

21. A method of manufacturing a flat panel display apparatus, the method comprising the steps of:
preparing a substrate on which a display unit is disposed;
disposing a sealing substrate to face the display unit;
forming a sealing member between the substrate and the sealing substrate so as to surround the display unit;
forming a wiring unit disposed between the substrate and the sealing substrate so as to overlap at least the sealing member, the wiring unit including a plurality of wiring members disposed apart from each other; and
forming an inlet unit electrically connected to an external power source and the wiring unit, the inlet unit including edges located in parallel with an outermost wiring member from among the plurality of wiring members;
wherein the step of forming the sealing member comprises disposing a material of the sealing member between the substrate and the sealing substrate, connecting the external power source to the inlet unit, and applying voltage to the wiring unit from the external power source and via the inlet unit so as to fuse and harden the material of the sealing member by using heat generated by the wiring unit.

22. The method of claim 21, wherein the material of the sealing member is obtained by preparing and baking a frit paste.

23. A method of manufacturing a mother substrate for a flat panel display apparatus, the method comprising the steps of:
preparing a substrate on which a plurality of display units are disposed to form a plurality of flat panel display apparatuses;
disposing a sealing substrate to face the plurality of display units;
disposing a sealing member between the substrate and the sealing substrate so as to respectively surround the plurality of display units;
disposing a plurality of wiring units between the substrate and the sealing substrate so as to respectively correspond to the plurality of display units and overlapping at least the sealing member, each of the plurality of wiring units including a plurality of wiring members disposed apart from each other;
forming a connection unit for connecting wiring units adjacent in one direction from among the plurality of wiring units, the connection unit including an edge connected in parallel with an outermost wiring member of the plurality of wiring units; and
forming an inlet unit electrically connected to an external power source and the plurality of wiring units, the inlet unit including an edge located in parallel with the outermost wiring member of the plurality of wiring members;
wherein the step of forming the sealing member comprises disposing a material of the sealing member between the substrate and the sealing substrate, connecting the external power source to the plurality of inlet units, and applying voltage to the plurality of wiring units from the external power source and via the inlet unit so as to fuse and harden the material of the sealing member by using heat generated by the wiring unit.

24. The method of claim 23, wherein the material of the sealing member is obtained by preparing and baking a frit paste.
